(19) United States
(12) Patent Application Publication
(10) Pub. No.: US 2022/0209211 A1
(43) Pub. Date: Jun. 30, 2022

(54) MASKS AND MANUFACTURING METHODS OF MASKS

(71) Applicant: Kunshan Go-Visionox Opto-Electronics Co., Ltd., Kushan (CN)

(72) Inventors: Chen Zhang, Kunshan (CN); Jijun Jiang, Kunshan (CN)

(73) Assignee: Kunshan Go-Visionox Opto-Electronics Co., Ltd., Kushan (CN)

(21) Appl. No.: 17/693,557

(22) Filed: Mar. 14, 2022

Related U.S. Application Data
(63) Continuation of application No. PCT/CN2021/074011, filed on Jan. 27, 2021.

(30) Foreign Application Priority Data
Mar. 23, 2020 (CN) 202010207412.8

(51) Int. Cl. H01L 51/56; G03F 1/50; H01L 27/32; H01L 51/00

(52) U.S. Cl. CPC H01L 51/56; G03F 1/50; H01L 2227/323; H01L 51/0018; H01L 27/3246

(57) ABSTRACT

The present application relates to a mask, and a manufacturing method of the mask. The mask includes a transparent region corresponding to a pixel opening region of the display panel, a semi-transparent region corresponding to a pixel defining layer region of the display panel, and a non-transparent region corresponding to a support pillar region of the display panel. The transparent region and the non-transparent region are surrounded by the semi-transparent region.

### CROSS-REFERENCE TO RELATED APPLICATIONS

This application is a continuation of international patent application No. PCT/CN2021/074011, filed on Jan. 27, 2021, which claims the benefit of Chinese patent application No. 202010207412.8, filed on Mar. 23, 2020. The contents of both applications are hereby incorporated by reference in their entireties.

### TECHNICAL FIELD

The present application relates to the field of display technology.

### BACKGROUND

The organic light emitting display (OLED) is a promising display technology. The OLED device has excellent display performance as well as the characteristics of self-luminescence, simple structure, ultrathin thickness, fast response speed, wide viewing angle, low power consumption, flexible display, etc.

### SUMMARY

The present invention provides a mask and a manufacturing method of the mask, which reduces the number of the masking steps required in the OLED panel manufacturing process, while simplifying the manufacturing process.

In an embodiment, a mask for manufacturing a display panel is provided. The mask includes a transparent region corresponding to a pixel opening region of the display panel, a semi-transparent region corresponding to a pixel defining layer region of the display panel, and a non-transparent region corresponding to a support pillar region of the display panel. The transparent region and the non-transparent region are surrounded by the semi-transparent region.

In an embodiment, a mask for manufacturing a display panel is provided including a transparent region configured to allow the exposure energy to completely penetrate throughout, a non-transparent region configured to prevent the exposure energy penetrating throughout, and a semi-transparent region configured to allow a part of the exposure energy to penetrate throughout and respectively enclose the transparent region and the non-transparent region to separate the transparent region from the non-transparent region.

In another embodiment, a manufacturing method of a mask for manufacturing a display panel is provided, including:

forming a transparent region corresponding to a pixel opening region of the display panel;

forming a non-transparent region corresponding to a support pillar region of the display panel; and

forming a semi-transparent region corresponding to a pixel defining layer region of the display panel;

wherein the transparent region and the non-transparent region are surrounded by the semi-transparent region.

In the technical solution of the embodiments of the present disclosure, the mask includes the transparent region, the semi-transparent region, and the non-transparent region, wherein the transparent region is used to form the pixel opening of the display panel, the semi-transparent region is used to form the pixel defining layer of the display panel, and the non-transparent region is used to form the support pillar of the display panel. Three structures including the pixel opening, the pixel defining layer, and the support pillar can be simultaneously formed by performing a single masking step using the mask according to the present disclosure, reducing the number of masking steps required in the manufacturing process of the OLED panel and simplifying the manufacturing process.

### BRIEF DESCRIPTION OF THE DRAWINGS

FIG. 1 is a schematic diagram of exposing an organic adhesive layer through a mask according to an embodiment of the present disclosure.

FIG. 2 is a schematic structural view of the three structures including a pixel opening, a support pillar, and a pixel defining layer of a display panel according to an embodiment of the present disclosure.

FIG. 3 is a schematic top structural view of a mask according to an embodiment of the present disclosure.

FIG. 4 is a schematic side view of the three structures, a pixel opening, a support pillar, and a pixel defining layer of a display panel according to another embodiment of the present disclosure.

FIG. 5 is a graph showing the relationship between a height h of a support pillar and a distance d between an edge of the support pillar and an edge of a pixel opening according to an embodiment of the present disclosure.

FIG. 6 is a schematic structural view of a display panel according to an embodiment of the present disclosure.

FIG. 7 is a flow chart of a manufacturing method of a mask according to an embodiment of the present disclosure.

FIG. 8 is a graph showing the relationship between a thickness of a pixel defining layer and a light transmittance of a semi-transparent region of a mask and the relationship between a slope angle α of the pixel defining layer and the light transmittance of the semi-transparent region of the mask according to an embodiment of the present disclosure.

### DETAILED DESCRIPTION OF THE EMBODIMENTS

The present disclosure is further described in detail below with reference to the accompanying drawings and the embodiments. It should be understood that the specific embodiments described herein are merely illustrative of the present disclosure rather than limitations thereto. In addition, it should be noted that only part but not all of the structures related to the present disclosure are shown in the drawings for the convenience of description.

In the conventional OLED panel manufacturing process, the patterned layers of the display panel are primarily formed with masks through masking steps. The set patterns of the masks are replicated to the layers of the display panel through the exposure and development processing. This manufacturing process of the OLED panel requires several masking steps and is thus complicated and increases the manufacturing cost of the display panel.

In the conventional OLED panel manufacture, a plurality of pattern processes require many different masks. For example, in the formation of a pixel defining layer, an organic adhesive layer is coated on an OLED anode, a pixel opening is formed in the organic adhesive layer via a mask, and then a support pillar is formed via another mask. That is, two masking steps are performed to form the three structures of the pixel defining layer, the pixel opening, and the support pillar. Therefore, the manufacturing process is relatively complex.

In view of this, the present disclosure provides a mask including a transparent region, a semi-transparent region, and a non-transparent region. The transparent region and the non-transparent region are surrounded by a semi-transparent region. The transparent region is used to form a pixel opening of a display panel. The semi-transparent region is used to form a pixel defining layer (PDL) of the display panel. The non-transparent region is used to form a support pillar of the display panel. When an organic adhesive layer on an anode is exposed and developed with the mask, the pixel defining layer, the pixel opening, and the support pillar can be formed simultaneously, thereby saving one masking step and simplifying the manufacturing process.

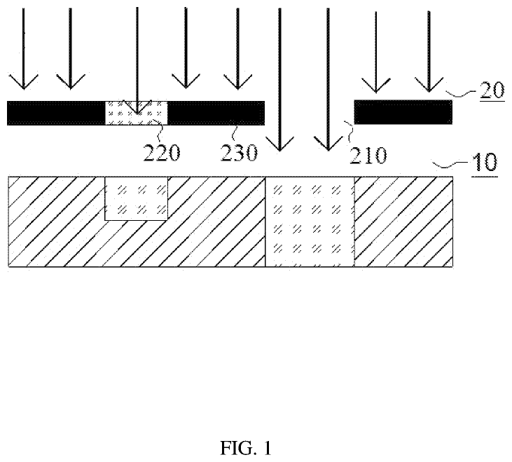

In an embodiment, a mask 20 includes a transparent region 210, a semi-transparent region 220, and a non-transparent region 230, as shown in FIG. 1. The transparent region 210 is configured to allow the exposure energy to completely penetrate throughout. The non-transparent region 230 is configured to prevent the exposure energy penetrating throughout. The semi-transparent region 220 is configured to allow part of the exposure energy to penetrate throughout. The semi-transparent region 220 is respectively enclosed to the transparent region 210 and the non-transparent region 230 to separate the transparent region 210 from the non-transparent region 230. When an organic adhesive layer 10 is coated on an anode of a display panel and then exposed through the mask as shown in FIG. 1, the exposure energy will substantially pass through the transparent region 210 in its entirety, barely pass through the non-transparent region 230, and partially pass through the semi-transparent region 220. A first portion of the organic adhesive layer 10 can be positioned corresponding to the transparent region 210 of the mask. A second portion of the organic adhesive layer 10 can be positioned corresponding to the semi-transparent region 220 of the mask. A third portion of the organic adhesive layer 10 can be positioned corresponding to the non-transparent region 230 of the mask. Thus, by using the mask 20, the first portion of the organic adhesive layer 10 can be substantially exposed in its entirety, the third portion of the organic adhesive layer 10 cannot be exposed, and the second portion of the organic adhesive layer 10 can be partially exposed.

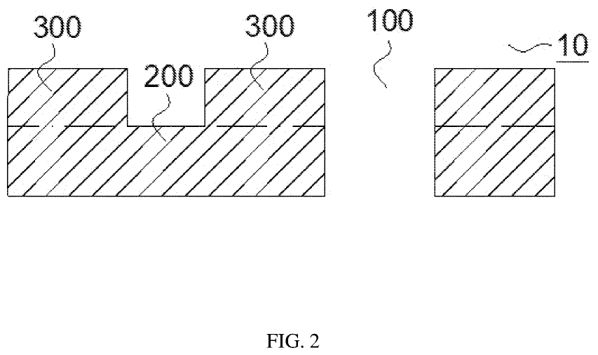

As shown in FIG. 2, after the development process, the first portion of the organic adhesive layer 10 positioned corresponding to the transparent region 210 of the mask is removed in its entirety to form a pixel opening 100 of the display panel, the third portion of the organic adhesive layer 10 positioned corresponding to the non-transparent region 230 of the mask is retained in its entirety to form a support pillar 300 of the display panel, and the second portion of the organic adhesive layer 10 positioned corresponding to the semi-transparent region 220 of the mask is partially removed to form a pixel defining layer 200 of the display panel. In some embodiments, the second portion of the organic adhesive layer 10 being partially removed means that the material of the second portion of the organic adhesive layer 10 is partially removed starting from the exposed surface of the organic adhesive layer 10 along a thickness direction of the organic adhesive layer 10, so that a thickness of the second portion of the organic adhesive layer 10 is reduced. The positional relationship between the pixel opening, the pixel defining layer, and the support pillar of the display panel can refer to the related art, and will not be repeated herein.

Therefore, the three structures, the pixel opening, the pixel defining layer, and the support pillar of the display panel can be simultaneously formed in a single exposure and development process by using the mask as shown in FIG. 1. Compared with the two exposure and development processes with two different masks, one masking step is omitted, thus simplifying the manufacturing process.

In an embodiment, the mask includes a first film layer disposed in the non-transparent region 230 to prevent the exposure energy penetrating throughout and a second film layer disposed in the semi-transparent region 220 to let part of the exposure energy penetrate throughout. The light transmittance of the second film layer is greater than the light transmittance of the first film layer. The light transmittance of the first film layer can be zero. The transparent region 210 of the mask can be configured as an opening area. Alternatively, the mask includes a third film layer disposed in the transparent region 210, and the light transmittance of the third film layer is 100%. The third film layer can be made of a transparent material.

In an embodiment, the second film layer can be a chromium oxide layer, and the first film layer may be a chromium metal layer. The chromium metal layer can block the exposure energy from passing through the non-transparent region 230 of the mask. The chromium oxide layer, which has a light transmittance greater than that of the chromium metal layer, allowing the exposure energy to partially pass through the semi-transparent region 220 of the mask.

In this embodiment, by providing different layers in different regions of the mask, the mask can have different light transmittances at different regions, so that different portions of the organic adhesive layer 10 of the display panel can be exposed to different extents to form the pixel opening, the support pillar, and the pixel defining layer simultaneously in one masking step, which simplifies the manufacturing process.

The thicknesses of the chromium oxide layer and the chromium metal layer can be set according to the actual needs and requirements for the light transmittances, and is not specifically limited in the present disclosure. In other embodiments, the layers of other materials can also be provided in the semi-transparent region 220 and the non-transparent region 230 of the mask by those skilled in the art as needed, as long as the exposure energy cannot pass through the non-transparent region 230 of the mask but can partially pass through the semi-transparent region 220 of the mask, and the materials of the layers are not specifically limited in the present disclosure.

In an embodiment, a thickness of the pixel defining layer formed after the development can be adjusted by adjusting the light transmittance of the semi-transparent region 220 of the mask to cause the second portion of the organic adhesive layer 10 of the display panel to be exposed to different extents. In an embodiment, the light transmittance of the semi-transparent region is set as 20% to 40% to obtain the pixel defining layer with a thickness meeting the actual production requirements.

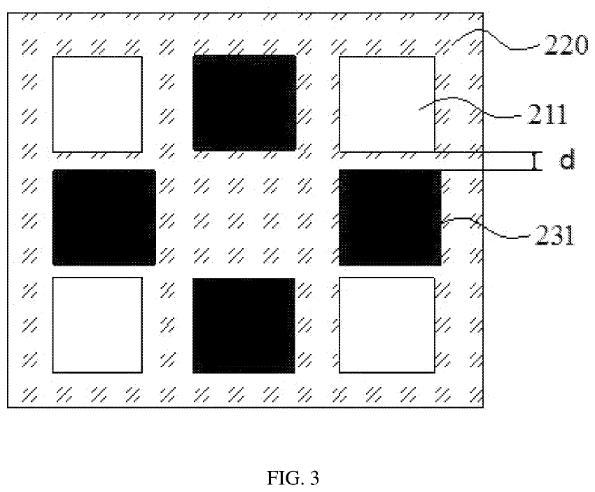

In an embodiment, as shown in FIG. 3 which is a schematic top view of the mask, the transparent region 210 includes a plurality of transparent sub-regions 211 separate from each other. The plurality of transparent sub-regions 211 is used to form a plurality of pixel openings 100 of the display panel. The non-transparent region 230 includes a plurality of non-transparent sub-regions 231 separate from each other. At least one non-transparent sub-region 231 is provided between two adjacent ones of the transparent sub-regions 211. The plurality of non-transparent sub-regions 231 is used to form a plurality of support pillars 300 of the display panel. The transparent sub-regions 211 and the non-transparent sub-regions 231 are each separately enclosed by the semi-transparent region 220. In this way, at least one support pillar can be formed between two adjacent pixel openings of the display panel, which is beneficial to the formation of sub-pixels.

In an embodiment, the first film layer comprises a plurality of first sub-layers separate from each other and disposed in the respective non-transparent sub-regions 231. The plurality of transparent sub-regions 211 is configured as a plurality of opening areas. The second film layer is a continuous film layer enclosing each of the first sub-layers and each of the opening areas to separate the first sub-layers from the opening areas. Any one of the first sub-layers is disposed between two adjacent opening areas.

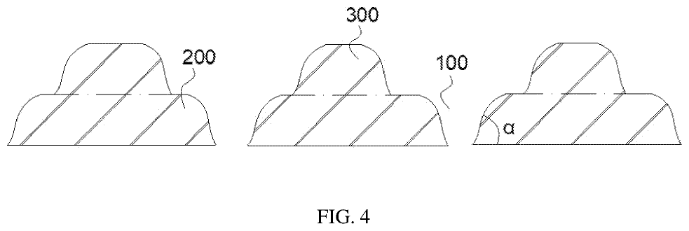

As shown in FIG. 4, the inventor found that in the process of forming the support pillar, the pixel opening, and the pixel defining layer via one exposure and development process with the mask, since the organic adhesive forming the organic adhesive layer 10 has a certain fluidity before the organic adhesive layer 10 is dried and completely solidified, the support pillar 300 may sink into and merge with the organic adhesive forming the pixel defining layer and surrounding it before the organic adhesive layer 10 is completely solidified. The sinking of the support pillar 300 will affect the height of the support pillar, and further affect the consistency of the subsequent encapsulating layer. The inventor found that the sinking of the support pillar 300 in the solidifying process can be effectively controlled by reducing the distance d between an edge of the support pillar 300 and an edge of the pixel opening adjacent to the support pillar 300, that is, the sinking of the support pillar 300 can be effectively controlled by controlling the distance d between an edge of the non-transparent sub-region 231 and an edge of the transparent sub-region 211 adjacent to the non-transparent sub-region 231.

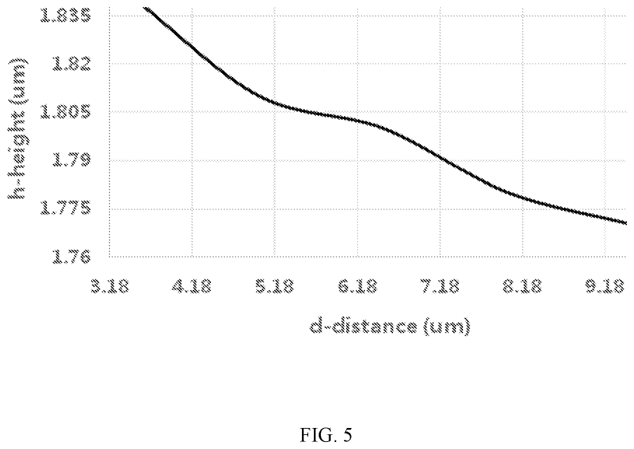

As shown in FIG. 5, the inventor found that there is a relationship between the minimum distance d between the edge of the support pillar and the edge of the pixel opening adjacent to the support pillar 300 (i.e., the minimum distance d between the edge of the non-transparent sub-region 231 and the edge of the transparent sub-region 211 adjacent to the non-transparent sub-region 231) and a height h of the support pillar. When the minimum distance d is 10 μm, the height h of the support pillar after the solidification is the minimum height that can meet the requirements for encapsulation. In some embodiments, in order to ensure that the height of the support pillar after solidification can meet the requirements for encapsulation, the minimum distance d between the edge of the support pillar and the edge of the pixel opening adjacent to the support pillar is smaller than or equal to 10 μm, that is, the minimum distance between the edge of the non-transparent sub-region 231 and the edge of the transparent sub-region 211 adjacent to the non-transparent sub-region 231 of the mask is smaller than or equal to 10 μm.

In some embodiments, by setting the minimum distance between the edge of the non-transparent sub-region 231 and the edge of the transparent sub-region 211 of the mask as being smaller or equal to 10 μm, the sinking of the support pillar 300 in the subsequent display panel manufacturing process can be effectively controlled so that the final height of the support pillar 300 can be maintained in a acceptable range, and the adverse effect on the subsequent encapsulation can be avoided.

In another embodiment, the transparent region 210 includes a plurality of transparent sub-regions 211 separate from each other. The plurality of transparent sub-regions 211 is used to form a plurality of pixel openings 100 of the display panel. The non-transparent region 230 includes a plurality of non-transparent sub-regions 231 separate from each other. Two or more non-transparent sub-regions 231 are provided between two adjacent transparent sub-regions 211 to form two or more support pillars 300 between two adjacent pixel openings 100 of the display panel. The plurality of sub-transparent regions 211 and the plurality of non-transparent sub-regions 231 are each separately surrounded by the semi-transparent region 220. A distance of edges of any two adjacent support pillars is smaller than or equal to 10 μm. That is, a distance of edges of any two adjacent non-transparent sub-regions 231 is smaller than or equal to 10 μm.

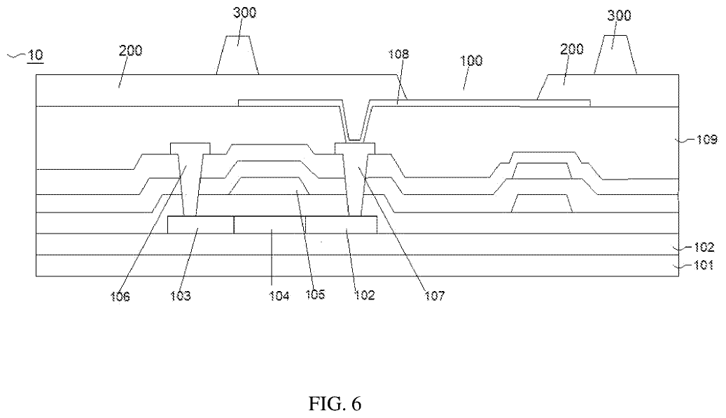

In an embodiment, a display panel is further provided. As shown in FIG. 6, the display panel includes the pixel opening 100, the pixel defining layer 200, and the support pillar 300 which are formed simultaneously via one exposure and development process using the mask as described above.

Other film/layer structures of the display panel are known in the related art. For example, the display panel may also include a substrate 101, a drain electrode 102, a source electrode 103, a channel 104, a gate electrode 105, an anode 108, a planarization layer 109, etc. The source electrode 103 is in electrical contact with the signal line through a hole 106 in the source electrode region, and the drain electrode 102 is in electrical contact with the anode 108 through a hole 107 in the drain electrode region. The details of these film/layer structures can refer to the related art, and will not be repeated herein.

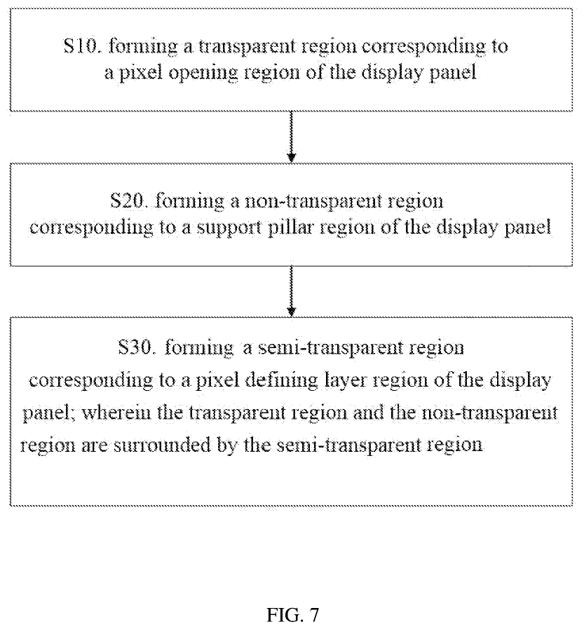

In an embodiment, a manufacturing method of the mask for manufacturing the display panel is provided, as shown in FIG. 7. The manufacturing method includes:

S10, forming the transparent region corresponding to a pixel opening region of the display panel;

S20, forming the non-transparent region corresponding to a support pillar region of the display panel; and

S30, forming the semi-transparent region corresponding to a pixel defining layer region of the display panel;

wherein the transparent region and the non-transparent region are surrounded by the semi-transparent region.

It should be noted that the formation order of the transparent region, the non-transparent region, and the semi-transparent region of the mask is not specifically limited in this embodiment, as long as the above three regions can be formed in the end.

Specifically, step S30 further includes determining the light transmittance of the semi-transparent region and forming the semi-transparent region according to the determined light transmittance. The step of determining the light transmittance of the semi-transparent region specifically includes:

S31, determining the energy density of exposure energy;

S32, exposing and developing organic adhesive layers, which have the same parameters (such as the material and the thickness) as the organic adhesive layer for use in the manufacturing process of the display panel, through calibration masks with different light transmittances, thereby obtaining pixel defining layers with different thicknesses including;

S33, selecting a pixel defining layer having an optimal thickness from the pixel defining layers with different thicknesses; and

S34, determining the light transmittance of the semi-transparent region as the light transmittance of the calibration mask (i.e. or referred to as the optimal light transmittance) with which the pixel defining layer having the optimal thickness is obtained.

In this embodiment, under the comprehensive effect of the two variables, i.e., the energy density of the exposure energy and the light transmittance of the semi-transparent region of the mask, the pixel defining layer with different thicknesses can be obtained. In order to determine the light transmittance of the semi-transparent region of the mask, another variable, i.e., the energy density of the exposure energy, is fixed firstly. With the energy density of the exposure energy fixed, the pixel defining layers with different thicknesses can be obtained by adjusting the light transmittances of the calibration masks. The required light transmittance of the semi-transparent region of the mask can be inversely deduced by selecting the optimal thickness of the pixel defining layer which is suitable for evaporating sub-pixels.

The energy density of the exposure energy determined in the step S31 can be used as the energy density of the exposure energy with which the organic adhesive layer coated on the anode is exposed in the manufacturing process of the display panel. The energy density of the exposure energy should be large enough for the organic adhesive layer 10 of the display panel to be completely removed, so as to prevent any residual organic adhesive which will affect the subsequent normal process.

In an embodiment, the energy density of the exposure energy is 170-220 mj/cm², which not only enables the organic adhesive layer 10 to be completely removed after receiving the full exposure energy, and but also has no adverse effect on the anode of the display panel.

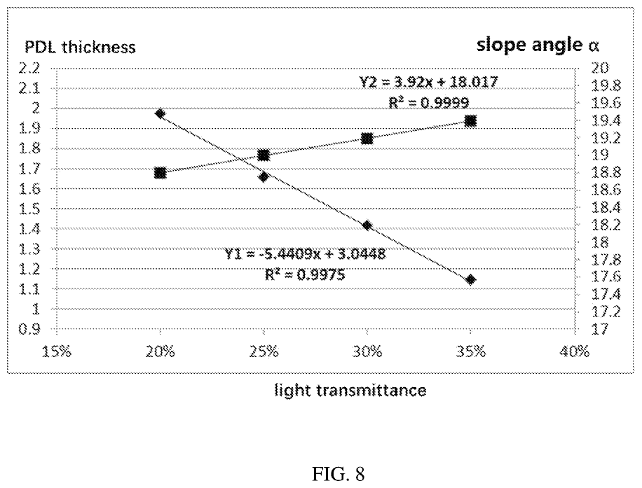

With the energy density of the exposure energy fixed, the pixel defining layers with different thicknesses can be obtained by using one or more calibration masks with different light transmittances. The inventor found that there is a relationship between the light transmittance of the calibration mask (i.e., the light transmittance of the semi-transparent region) and the thickness of the pixel defining layer, as shown with the curve Y1 in FIG. 8.

In addition, since the organic adhesive of the organic adhesive layer 10 has a certain fluidity, the organic adhesive layer 10 may collapse downward before it is dried and completely solidified. Therefore, as shown in FIG. 4, a slope angle α (i.e., the angle between the side surface and the bottom surface of the pixel defining layer 200) may be formed at a side of the pixel defining layer 200 formed after the solidification adjacent to the pixel opening 100. There is a linear relationship between the slope angle α and the light transmittance of the calibration mask and a linear relationship between the thickness of the pixel defining layer and the light transmittance of the calibration mask, as shown with curves Y1 and Y2 in FIG. 8. The optimal thickness of the pixel defining layer and the corresponding optimal light transmittance of the calibration mask can be determined from the intersection point of Y1 and Y2.

In this embodiment, by obtaining the relationship between the thickness of the pixel defining layer and the light transmittance of the calibration mask and the relationship between the slope angle α and the light transmittance of the calibration mask and determining the intersection point of the curves Y1 and Y2 indicating the two relationships, the optimal thickness of the pixel defining layer and the corresponding optimal light transmittance of the calibration mask can be determined. Because at this intersection point, the thickness of the pixel defining layer is balanced such that not only the slope angle α will not be too smaller and the extent of the downward collapse of the thickness of the pixel defining layer will not too great, but also the requirements of evaporation of the sub-pixels can be satisfied.

Furthermore, according to the obtained optimal light transmittance of the calibration mask, the optimal light transmittance of the semi-transparent region 220 of the mask can be determined. Specifically, a semi-transparent layer with the optimal light transmittance can be provided in the semi-transparent region 220. Specifically, the semi-transparent region 220 of the mask can be provided with a chromium oxide layer, and the non-transparent region 230 can be provided with a chromium metal layer. The chromium metal layer can block the exposure energy from passing through the non-transparent region 230 of the mask. The chromium oxide layer, which has a light transmittance greater than that of the chromium metal layer, allows the exposure energy to partially pass through the semi-transparent region 220 of the mask. In this embodiment, by providing different layers in different regions of the mask, the mask can have different light transmittances at different regions so that different portions of the organic adhesive layer 10 of the display panel can be exposed to different extents to form the pixel opening, the support pillar, and the pixel defining layer simultaneously in a single masking step, which simplifies the manufacturing process.

The thicknesses of the chromium oxide layer and the chromium metal layer can be set according to actual needs to meet the actual requirements for the light transmittances, and is not specifically limited in the present disclosure. In other embodiments, the layers of other materials can also be provided in the semi-transparent region 220 and the non-transparent region 230 of the mask by those skilled in the art as needed, as long as the exposure energy cannot pass through the non-transparent region 230 of the mask but can partially pass through the semi-transparent region 220 of the mask, and the materials of the layers are not specifically limited in the present disclosure.

In an embodiment, a method for manufacturing the display panel is provided, including:

forming an array substrate;

forming an anode on the array substrate;

coating an organic adhesive layer on the anode;

exposing the organic adhesive layer through the mask including the transparent region, the semi-transparent region, and the non-transparent region;

developing the organic adhesive layer to form the pixel defining layer, the pixel openings distributed in the pixel defining layer, and the support pillar located on a region of the pixel defining layer provided with no pixel opening, wherein the transparent region of the mask corresponds to a region of the display panel where the pixel opening is formed, the non-transparent region corresponds to a region of the display panel where the support pillar is formed, and the semi-transparent region corresponds to a region of the display panel where the pixel defining layer is formed; and

evaporating a sub-pixel in the pixel opening, and forming an encapsulating layer on the sub-pixel.

The energy density of the exposure energy is 170˜220 mj/cm².

The energy density of the exposure energy received by the second portion of the organic adhesive layer corresponding to the semi-transparent region of the mask is 20%-40% of the energy density of the exposure energy received by the first portion of the organic adhesive layer corresponding to the transparent region of the mask.

It should be noted that the above description is only the preferred embodiments of the present disclosure and the technical principles applied. Those skilled in the art would understand that the present disclosure is not limited to the specific embodiments described herein, and various obvious modification, readjustments and substitutions can be made by those skilled in the art without departing from the protection scope of the present disclosure. Therefore, although the present disclosure has been explained in more detail through the above embodiments, the present disclosure is not limited to the above embodiments, and can also include more other equivalent embodiments without departing from the concept of the present disclosure. The scope of the present disclosure is determined by the appended claims.

What is claimed is:

1. A mask for manufacturing a display panel, comprising:
a transparent region corresponding to a pixel opening region of the display panel;
a semi-transparent region corresponding to a pixel defining layer region of the display panel; and
a non-transparent region corresponding to a support pillar region of the display panel, wherein the transparent region and the non-transparent region are surrounded by the semi-transparent region.

2. The mask according to claim 1, wherein the semi-transparent region is provided with a chromium oxide layer, and the non-transparent region is provided with a chromium metal layer.

3. The mask according to claim 1, wherein a light transmittance of the semi-transparent region is 20% to 40%.

4. The mask according to claim 1, wherein:
the transparent region comprises a plurality of transparent sub-regions separate from each other;
the non-transparent region comprises a plurality of non-transparent sub-regions separate from each other; and
the non-transparent sub-regions are provided between two adjacent transparent sub-regions.

5. The mask according to claim 1, wherein a distance between an edge of the non-transparent sub-region and an edge of the transparent sub-region adjacent to the non-transparent sub-region is smaller than or equal to 10 μm.

6. A mask, for manufacturing a display panel, comprising:
a transparent region configured to let the exposure energy penetrate therethrough;
a non-transparent region configured to prevent the exposure energy penetrating therethrough;
a semi-transparent region configured to let part of the exposure energy penetrate therethrough and respectively enclose the transparent region; and
the non-transparent region to separate the transparent region from the non-transparent region.

7. The mask according to claim 6, further comprising a first film layer disposed in the non-transparent region to prevent the exposure energy penetrating therethrough;
wherein a second film layer disposed in the semi-transparent region to let part of the exposure energy penetrate therethrough; and
wherein the light transmittance of the second film layer is greater than the light transmittance of the first film layer and the light transmittance of the first film layer is zero.

8. The mask according to claim 7, wherein the transparent region is configured as an opening area; or
the transparent region is disposed with a third film layer and the light transmittance of the third film layer is 100%.

9. The mask according to claim 7, wherein the transparent region comprises:
a plurality of transparent sub-regions separate from each other;
wherein the first film layer comprises a plurality of first sub-layers separate from each other;
wherein the second film layer encloses the transparent sub-regions;
wherein the first sub-layers to separate the transparent sub-regions from the first sub-layers; and
wherein the first sub-layers are disposed between two adjacent transparent sub-regions.

10. A manufacturing method of a mask for manufacturing a display panel, comprising:
forming a transparent region corresponding to a pixel opening region of the display panel;
forming a non-transparent region corresponding to a support pillar region of the display panel; and
forming a semi-transparent region corresponding to a pixel defining layer region of the display panel;
wherein the transparent region and the non-transparent region are surrounded by the semi-transparent region.

11. The manufacturing method according to claim 10, wherein the forming the semi-transparent region comprises:
determining a light transmittance of the semi-transparent region, and
forming the semi-transparent region with the determined light transmittance.

12. The manufacturing method according to claim 11, wherein the determining the light transmittance of the semi-transparent region comprises:
determining the energy density of the exposure energy;
exposing and developing organic adhesive layers through calibration masks with different light transmittances, thereby obtaining pixel defining layers with different thicknesses;
selecting a pixel defining layer having an optimal thickness from the pixel defining layers with different thicknesses; and
determining the light transmittance of the semi-transparent region as the light transmittance of the calibration mask with which the pixel defining layer having the optimal thickness is obtained.

13. The manufacturing method according to claim 12, wherein the selecting the pixel defining layer having the optimal thickness from the pixel defining layers with different thicknesses comprises:
establishing a first relationship curve between the light transmittance of the calibration mask and the thickness of the pixel defining layer;
establishing a second relationship curve between a slope angle of the pixel defining layer and the light transmittance of the calibration mask; and
determining a thickness of the pixel defining layer corresponding to the intersection point of the first relationship curve and the second relationship curve as the optimal thickness of the pixel defining layer.

14. The manufacturing method according to claim 11, wherein the semi-transparent region is provided with a semi-transparent layer with the determined light transmittance.

15. The manufacturing method according to claim 11, wherein the energy density of the exposure energy is the same as the energy density of the exposure energy actually used to expose the organic adhesive layer in the manufacture process of the display panel.

16. The manufacturing method according to claim 15, wherein the energy density of exposure energy is 170 to 220 mj/cm².
